(19) United States
(12) Patent Application Publication
(10) Pub. No.: US 2011/0189406 A1
(43) Pub. Date: Aug. 4, 2011

(54) METHOD OF FORMING GRAPHENE LAYER

(75) Inventors: Byung Jin Cho, Daejeon (KR); Jeong Hun Mun, Daejeon (KR)

(73) Assignee: Korea Advanced Institute of Science and Technology, Daejeon (KR)

(21) Appl. No.: 12/705,187

(22) Filed: Feb. 12, 2010

(30) Foreign Application Priority Data
Feb. 1, 2010 (KR) 10-2010-0008936

(51) Int. Cl. C23C 14/48

(52) U.S. Cl. 427/523

(57) ABSTRACT

The present invention relates to a method of forming a graphene layer, and, more particularly, to a method of forming a graphene layer which is a two-dimensional thin film composed of carbon atoms arranged in a honeycomb-style lattice and having one atom thick and which is put to practical use in the field of electric devices, transparent electrodes or microwave circuits. The method includes the steps of: (a) forming a metal thin film on a substrate; (b) injecting carbon ions into the metal thin film; and (c) heat-treating the carbon ions injected into the metal thin film to form a graphene layer on the metal thin film. The method is advantageous in that a graphene layer is formed by uniformly injecting an accurate amount of carbon ions into a metal thin film depending on the maximum solubility of carbon in the metal thin film and then heat-treating the injected carbon ions, thus uniformly forming the graphene layer on the metal thin film.

### BACKGROUND OF THE INVENTION

1. Technical Field

The present invention relates to a method of forming a graphene layer, and, more particularly, to a method of forming a graphene layer which is a two-dimensional thin film composed of carbon atoms arranged in a honeycomb-style lattice and having one atom thick and which is put to practical use in the field of electric devices, transparent electrodes or microwave circuits.

2. Description of the Related Art

Graphene is a two-dimensional thin film composed of carbon atoms arranged in a honeycomb-style lattice and bound together with a sp² bond so as to have one atom thick. Graphene has a very high electron mobility of 100,000 cm²/V·s or more because electrons move in the graphene as if their masses do not exist.

Further, graphene is advantageous in that it can be produced using currently-available CMOS technology because it has a two-dimensional shape unlike carbon nanotubes which have a cylindrical shape. Therefore, graphene is in the spotlight as a next-generation semiconductor device which will replace current semiconductor devices.

Conventional methods of forming a graphene layer may include a method of forming a graphene layer by heat-treating a silicon carbide (SiC) substrate at high temperature in high vacuum, a method of forming a graphene layer by reducing oxidized graphene dispersed in a solvent and a method of forming a graphene layer on a metal thin film using a chemical vapor deposition (CVD) process. Currently, among the conventional methods, the method of forming a graphene layer using a chemical vapor deposition (CVD) process is being frequently used because a large-area graphene layer can be produced at low cost by this method.

In the method of forming a graphene layer using a chemical vapor deposition (CVD) process, a metal thin film is heated at normal pressure and high temperature under a hydrocarbon atmosphere to pyrolyze hydrocarbon gas into carbon atoms and hydrogen atoms, and then the pyrolyzed carbon atoms are dispersed in the metal thin film and then cooled to separate oversaturated carbon atoms from the surface of the metal thin film, thereby forming a graphene layer on the metal thin film.

This method of forming a graphene layer using a chemical vapor deposition (CVD) process is advantageous in that the cost of fabricating a substrate is lowered because an expensive monocrystalline substrate is not used in this method, and in that a large-area graphene layer can be easily formed because the CVD process used in this method is similar to that used in the manufacture of semiconductors and thus the size of a substrate is not limited.

However, this method of forming a graphene layer using a chemical vapor deposition (CVD) process is problematic in that it is not easy to accurately control the number of carbon atoms dispersed in the metal thin film during the process of pyrolyzing hydrocarbon gas by heating the metal thin film.

Further, this method of forming a graphene layer using a chemical vapor deposition (CVD) process is problematic in that it is difficult to ensure reproducibility in the formation of a graphene layer because the conditions for forming the graphene layer are sensitive to changes in the kind and amount of impurities remaining in a reactor and generated by performing previous processes.

### SUMMARY OF THE INVENTION

Accordingly, the present invention has been made to solve the above-mentioned problems, and an object of the present invention is to provide a method of forming a graphene layer, by which a uniform graphene layer can be formed on a metal thin film by accurately controlling the amount of carbon ions injected into the metal thin film in order to form the graphene layer on the metal thin film, and by which graphene layers having the same quality can be reproducibly formed on a metal thin film.

In order to accomplish the above object, an aspect of the present invention provides a method of forming a graphene layer, including the steps of: (a) forming a metal thin film on a substrate; (b) injecting carbon ions into the metal thin film; and (c) heat-treating the carbon ions injected into the metal thin film to form a graphene layer on the metal thin film.

In step (b), the injection rate of the carbon ions may be determined by the maximum solubility of carbon in the metal thin film.

Further, in step (c), the heat-treating of the carbon ions may be performed at a temperature of 600˜1000° C.

The method of forming a graphene layer may further include the step of: (a1) crystallizing the metal thin film formed in step (a), after step (a).

In step (a1), the crystallizing of the metal thin film may be performed by heat-treating the metal thin film formed in step (a) at a temperature of 800˜1000° C.

Further, in step (a1), the crystallizing of the metal thin film may be performed in a vacuum of 1˜760 torr.

Further, in step (b), the injecting of the carbon ions may be performed by an ion injector.

Further, in step (c), the heat-treating of the carbon atoms may be performed in a vacuum of 10⁻⁷˜10⁻³ torr.

Further, in step (a), the metal thin film may be made of any one selected from among nickel (Ni), platinum (Pt), gold (Au), copper (Cu), ruthenium (Ru), tungsten (W), cobalt (Co), lead (Pd), titanium carbide (Tic), tantalum carbide (TaC), and rhodium (Rd).

Further, in step (b), the injection rate of the carbon ions may be 1×10¹⁵ cm⁻²˜5×10¹⁵ cm⁻².

The method of forming a graphene layer may further include the step of: forming an insulating film on the substrate, before step (a).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flowchart showing a method of forming a graphene layer according to an embodiment of the present invention;

FIG. 2 is a graph showing the distribution of the injection rate of carbon ions injected into a metal thin film made of nickel (Ni) and the intensity of the ion energy thereof; and

FIG. 3 is a graph showing the results of Raman spectroscopy analysis of the graphene layer formed on a substrate using the method of forming a graphene layer according to an embodiment of the present invention.

### DESCRIPTION OF THE PREFERRED EMBODIMENTS

Hereinafter, preferred embodiments of the present invention will be described in detail with reference to the attached drawings. First, throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

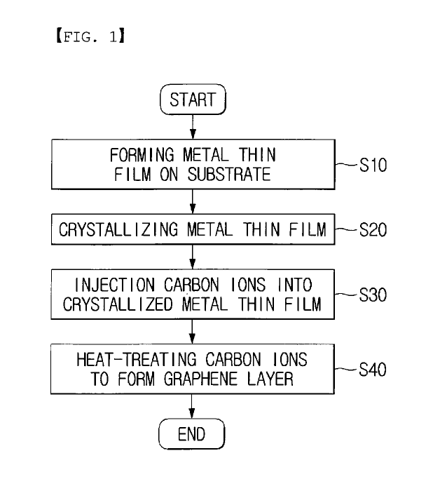

FIG. 1 is a flowchart showing a method of forming a graphene layer according to an embodiment of the present invention.

Here, each step of the method of forming a graphene layer according to an embodiment of the present invention may be performed in a reactor.

As shown in FIG. 1, first, in step 10 (S10), a metal thin film is formed on a substrate.

In this case, the substrate may be a silicon wafer. The metal thin film may be made of any one selected from among nickel (Ni), platinum (Pt), gold (Au), copper (Cu), ruthenium (Ru), cobalt (Co), lead (Pd), titanium carbide (TiC), tantalum carbide (TaC) and rhodium (Rd), each of which has a crystalline structure which can form a graphene layer thereon.

Further, the metal thin film may have a thickness of 100˜800 nm. The thickness of the metal thin film is set to the minimum value that allows the metal thin film to have a surface roughness which allows a graphene layer to be uniformly formed on the metal thin film during the heat treatment of the metal thin film formed on the substrate.

When the thickness of the metal thin film is less than 100 nm, metal atoms constituting the metal thin film rapidly agglomerate, so that the surface roughness of the metal thin film formed on the substrate increases after heat treatment, with the result that a graphene layer cannot be uniformly formed on the metal thin film.

The method may further include the step of forming an insulating film on the substrate prior to step 10 (S10).

In this case, the insulation film may be made of silicon oxide (SiO₂). The reason why the insulation film is formed on the substrate prior to the formation of the metal thin film in step 10 (S10) will be described below.

Subsequently, in step 20 (S20), the metal thin film formed on the substrate is crystallized.

The crystallization of the metal thin film may be performed by heat-treating the metal thin film formed on the substrate in a reactor at 800˜1000° C. In this case, in order to maintain a reducing atmosphere for preventing the oxidation of the metal thin film, a mixed gas of hydrogen and inert gas (H₂(10%)/Ar), in which hydrogen is diluted with argon such that the ratio of hydrogen to argon is 10%, may be introduced into the reactor, and the reactor may have a low vacuum of 1˜760 Torr.

As such, the crystallization of the metal thin film formed on the substrate in step 20 (S20) is performed in order to form a high-quality graphene layer on the metal thin film. As described above, the reason why the insulation film is formed on the substrate prior to the formation of the metal thin film in step 10 (S10) is to prevent the metal thin film from reacting with silicon during the heat treatment process for crystallizing the metal thin film formed on the substrate.

For example, when a metal thin film made of nickel (Ni) is formed on a silicon wafer, nickel (Ni) may react with silicon to form nickel silicide during the heat treatment process for crystallizing the metal thin film after the formation of the metal thin film.

Here, since a nickel (Ni) (111) crystal plane aligned such that it is optimally combined with a hexagonal graphene structure is necessarily required in order to form a high-quality graphene layer on the metal thin film made of nickel (Ni), it is preferable to prevent nickel silicide from being formed by the direct reaction of nickel and silicon during the heat treatment process for crystallizing the metal thin film by forming an insulating film made of silicon oxide (SiO₂) before the metal thin film is formed on the substrate.

Subsequently, in step 30 (S30), carbon ions are injected into the crystallized metal thin film.

In this case, the injection of carbon ions into the crystallized metal thin film may be performed using an ion injector. The reason why carbon ions are injected into the crystallized metal thin film using an ion injector is because an accurate amount of carbon ions can be uniformly injected into the crystallized metal thin film.

An example of step 30 (S30) will be described as follow.

The injection of carbon ions into the crystallized metal thin film may be performed by putting a substrate formed thereon with a metal thin film into an ion injector and then making the ion injector vacuous and then applying a carbon ion beam to the substrate at an angle of 0° or 7°.

In this case, the substrate may be patterned using photoresist or the like such that carbon ions can be injected into only a desired region of the substrate, and the carbon ions may be extracted from carbon dioxide gas using an analyzer magnet.

Meanwhile, in the process of injecting carbon ions into the metal thin film using the ion injector, the injection rate and ion energy intensity of carbon ions injected into the metal thin film must be considered. The reason for this is as follows.

First, carbon atoms must be distributed on the surface of the metal thin film to the utmost in order to separate the carbon atoms from the surface of the metal thin film during the process of forming a graphene layer after the injection of carbon ions. In this case, since the distribution of carbon ions is closely related to the ion energy of carbon ions, the ion energy of carbon ions injected into the metal thin film must be suitably controlled.

In this case, since the ion energy distribution of carbon ions injected into the metal thin film can be changed depending on the density of the metal thin film, the optimal ion energy of carbon ions injected into the metal thin film can be changed depending on the kind of metal constituting the metal thin film.

Further, the injection rate of carbon ions injected into the metal thin film must be controlled in order to separate a suitable amount of carbon atoms from the surface of the metal thin film during the process of forming a graphene layer after the injection of carbon ions. In this case, since the amount of carbon atoms separated from the surface of the metal thin film is determined by the maximum solubility of carbon in a metal constituting the metal thin film, the injection rate of carbon ions injected into the metal thin film must be suitably controlled depending on the maximum carbon solubility of the metal constituting the metal thin film.

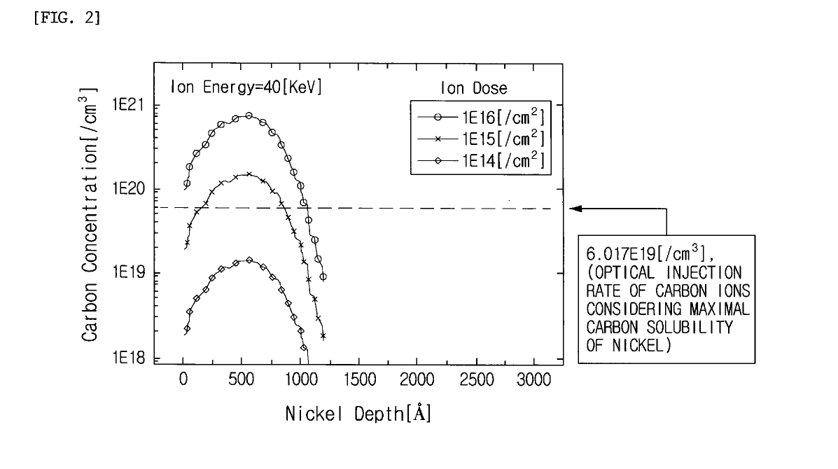

FIG. 2 is a graph showing the distribution of the injection rate of carbon ions injected into a metal thin film made of nickel (Ni) and the intensity of the ion energy thereof.

As shown in FIG. 2, in the case of a metal thin film made of nickel (Ni), it can be seen that the optimal injection rate of carbon ions for forming a graphene layer may be 1×10¹⁵˜5×10¹⁵ cm⁻², and the ion energy of carbon atoms for collectively distributing carbon atoms on the surface of nickel (Ni) may be about 40 KeV.

The above-mentioned injection rate and energy intensity of carbon ions correspond to the metal thin film made of nickel (Ni). Therefore, in the case of metal thin films made of metals other than nickel (Ni), the injection rate and energy intensity of carbon ions injected into the corresponding metal thin film can be changed depending on the maximum carbon solubility of the metals constituting the corresponding metal thin film and the density of the corresponding metal thin film.

Finally, in step 40 (S40), the carbons ions injected into the metal thin film are heat-treated to form a graphene layer on the metal thin film.

In this case, the heat treatment of the carbon ions injected into the metal thin film in the reactor is performed at a temperature of 600˜1000° C. The reactor has a high vacuum of 10⁻³˜10⁻⁷ torr, and this vacuum range is the minimal value required to form the carbon ions injected into the metal thin film into a graphene layer through heat treatment.

Further, the graphene layer may be formed on the metal thin film by heat-treating the carbon ions in step 40 (S40) and then cooling them and then separating carbon atoms from the surface of the metal thin film.

Further, observing the graphene layer formed on a substrate by a conventional CVD method and the graphene layer formed on a substrate by the method of forming a graphene layer according to an embodiment of the present invention, it is observed in the graphene layer formed on the substrate by the conventional CVD method that the graphene layer is nonuniform because it is formed by the separation of the carbon atoms which have been non-uniformly injected into the substrate, whereas it is observed in the graphene layer formed on the substrate by the method of forming a graphene layer according to an embodiment of the present invention that the graphene layer is very uniform.

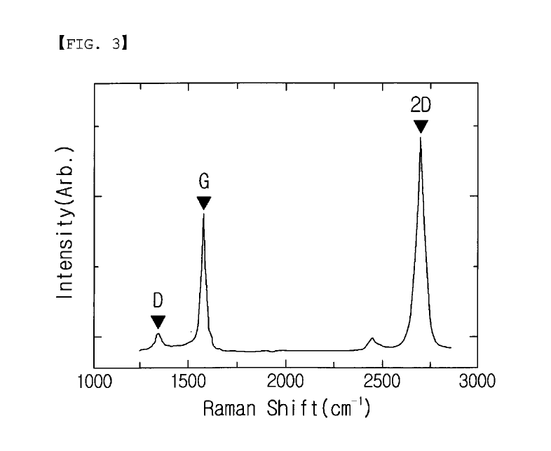

FIG. 3 is a graph showing the results of Raman spectroscopy analysis of the graphene layer formed on a metal thin film using the method of forming a graphene layer according to an embodiment of the present invention.

In FIG. 3, Raman spectroscopy analysis is performed using a laser having a wavelength of 514 nm.

Here, Raman spectroscopy is an optical analysis in which the characteristics of a specific substance are analyzed by measuring inelastic scattered light which is a part of scattered light obtained by applying light to the specific substance and scattering the light, this light having an energy different from incident light. Graphene is generally difficult to be optically approached because of its intrinsic physical properties, but the information on graphene can be collected by spectroscopic means. Therefore, Raman spectroscopy is necessarily used to analyze the properties of graphene because graphene can be clearly discriminated by this Raman spectroscopy.

As shown in FIG. 3, it can be seen from FIG. 3 that the D-peak (D) is very low. This means that the graphene layer formed by the method according to an embodiment of the present invention has few defects to such a degree that they are disregarded.

Further, it can be seen from FIG. 3 that the G-peak (G) is observed at about 1580 cm⁻¹ and that the 2D-peak (2D) is observed at about 2700 cm⁻¹. This means that the graphene layer formed by the method according to an embodiment of the present invention has a single layer structure.

Here, the G-peak means a peak which is commonly observed on a graph when graphite-based materials, such as graphite, carbon nanotubes, fullerene and graphene, are analyzed using Raman spectroscopy, the D-peak means a peak which is observed by the bonds in crystals when Raman spectroscopy is used, and the 2D-peak means a peak which is observed by secondary scattering when Raman spectroscopy is used.

Therefore, it can be seen from FIG. 3 that the graphene layer formed by the method according to an embodiment of the present invention has a uniform single layer structure and has few defects.

The method of forming a graphene layer according to the present invention, which is a method of forming a uniform graphene layer on a substrate formed thereon with a metal thin film, includes the steps of: forming a metal thin film on a substrate such as a silicon wafer or the like; uniformly injecting an accurate amount of carbon ions for forming a graphene layer into the metal thin film using an ion injector depending on the maximal carbon saturation fraction of the metal constituting the metal thin film; and heat-treating the injected carbon ions.

In the method, the amount of the carbon ions injected into the metal thin film can be accurately controlled, and the carbon ions can be entirely uniformly injected into the metal thin film, and thus the graphene layer formed by the heat treatment of the carbon ions injected into the metal thin film can be uniformly formed on the metal thin film.

Further, in the method, unlike conventional methods, since hydrocarbon gas is not used in a process of forming a graphene layer, a reactor in which the process of forming the graphene layer is performed is not contaminated, so that the graphene layer can be reproducibly formed on the metal thin film, and this method can be used regardless of the size and shape and the like of the reactor.

Therefore, when the method of forming a graphene layer according to the present invention is used, the mechanical, chemical and electrical properties of graphene can be effectively put to practical use in the fields of semiconductor memory devices, transparent electrodes or microwave circuits.

As described above, according to the present invention, since a graphene layer is formed by uniformly injecting an accurate amount of carbon ions into a metal thin film depending on the maximum carbon solubility of the metal thin film and then heat-treating the injected carbon ions, the graphene layer can be uniformly formed on the metal thin film.

Further, according to the present invention, since hydrocarbon gas is not additionally used in a process of forming the graphene layer, a reactor is not contaminated, so that the internal environment of the reactor can be maintained constant, thereby ensuring reproducible formation of the graphene layer.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Simple modifications, additions and substitutions of the present invention belong to the scope of the present invention, and the specific scope of the present invention will be clearly defined by the appended claims.

What is claimed is:

1. A method of forming a graphene layer, comprising the steps of:
(a) forming a metal thin film on a substrate;
(b) injecting carbon ions into the metal thin film; and
(c) heat-treating the carbon ions injected into the metal thin film to form a graphene layer on the metal thin film.

2. The method of forming a graphene layer according to claim 1, wherein, in step (b), an injection rate of the carbon ions is determined by a maximum solubility of carbon in the metal thin film.

3. The method of forming a graphene layer according to claim 1, wherein, in step (c), the heat-treating of the carbon ions is performed at a temperature of 600˜1000° C.

4. The method of forming a graphene layer according to claim 1, further comprising the step of: (a1) crystallizing the metal thin film formed in step (a), after step (a).

5. The method of forming a graphene layer according to claim 4, wherein, in step (a1), the crystallizing of the metal thin film is performed by heat-treating the metal thin film formed in step (a) at a temperature of 800˜1000° C.

6. The method of forming a graphene layer according to claim 4, wherein, in step (a1), the crystallizing of the metal thin film is performed in a vacuum of 1˜760 torr.

7. The method of forming a graphene layer according to claim 1, wherein, in step (b), the injecting of the carbon ions is performed by an ion injector.

8. The method of forming a graphene layer according to claim 1, wherein, in step (c), the heat-treating of the carbon atoms is performed in a vacuum of 10⁻⁷˜10⁻³ torr.

9. The method of forming a graphene layer according to claim 1, wherein, in step (a), the metal thin film is made of any one selected from among nickel (Ni), platinum (Pt), gold (Au), copper (Cu), ruthenium (Ru), tungsten (W), cobalt (Co), lead (Pd), titanium carbide (Tic), tantalum carbide (TaC), and rhodium (Rd).

10. The method of forming a graphene layer according to claim 1, wherein, in step (b), the injection rate of the carbon ions is 1×10¹⁵ cm^{-2˜}5×10¹⁵ cm⁻².

11. The method of forming a graphene layer according to claim 1, further comprising the step of: forming an insulating film on the substrate, before step (a).
